(19) United States
(12) Patent Application Publication
(10) Pub. No.: US 2025/0193992 A1
(43) Pub. Date: Jun. 12, 2025

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventor: Shinji NAGAI, Oyama-shi (JP)

(73) Assignee: Gigaphoton Inc., Tochigi (JP)

(21) Appl. No.: 18/934,912

(22) Filed: Nov. 1, 2024

(30) Foreign Application Priority Data
Dec. 11, 2023 (JP) 2023-208788

(51) Int. Cl. H05G 2/00; G03F 1/84; G03F 7/20

(52) U.S. Cl. CPC H05G 2/003; H05G 2/0027; H05G 2/0094; G03F 1/84; G03F 7/20

(57) ABSTRACT

An extreme ultraviolet light generation apparatus includes a chamber, a target supply unit supplying a droplet of a target substance toward a plasma generation region, a light concentrating mirror concentrating extreme ultraviolet light, a debris shield provided with a first opening through which the extreme ultraviolet light passes from the plasma generation region toward the light concentrating mirror and a second opening, a gas supply port supplying a gas to an internal space of the chamber, and an exhaust port exhausting a gas in a space surrounded by the debris shield. At least a part of the second opening is provided at a position symmetrical to at least a part of the first opening with reference to a plane including a trajectory of the laser light and a trajectory of the droplet. The gas at the internal space flows into the space through the first opening and the second opening.

### CROSS-REFERENCE TO RELATED APPLICATIONS

The present application claims the benefit of Japanese Patent Application Publication No. 2023/208788, filed on Dec. 11, 2023, the entire contents of which are hereby incorporated by reference.

### BACKGROUND

### 1. Technical Field

The present disclosure relates to an extreme ultraviolet light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: U.S. Pat. No. 6,493,423
Patent Document 2: U.S. Pat. No. 7,763,871
Patent Document 3: Japanese Patent Application Publication No. H09-245992

### SUMMARY

An extreme ultraviolet light generation apparatus according to an aspect of the present disclosure includes a chamber in which a target substance supplied to a plasma generation region at an internal space thereof is irradiated with laser light to generate extreme ultraviolet light, a target supply unit configured to supply a droplet of the target substance toward the plasma generation region, a light concentrating mirror arranged at the internal space and configured to concentrate the extreme ultraviolet light, a debris shield provided with a first opening through which the extreme ultraviolet light passes from the plasma generation region toward the light concentrating mirror and a second opening, and surrounding the plasma generation region, a gas supply port provided at the chamber and configured to supply a gas to the internal space, and an exhaust port configured to exhaust a gas in a space surrounded by the debris shield. Here, at least a part of the second opening is provided at a position symmetrical to at least a part of the first opening with reference to a plane including a trajectory of the laser light and a trajectory of the droplet. The gas at the internal space flows into the space through the first opening and the second opening.

An electronic device manufacturing method according to an aspect of the present disclosure includes outputting extreme ultraviolet light generated using an extreme ultraviolet light generation apparatus to an exposure apparatus, and exposing a photosensitive substrate to the extreme ultraviolet light in the exposure apparatus to manufacture an electronic device. Here, t extreme ultraviolet light generation apparatus includes a chamber in which a target substance supplied to a plasma generation region at an internal space thereof is irradiated with laser light to generate the extreme ultraviolet light, a target supply unit configured to supply a droplet of the target substance toward the plasma generation region, a light concentrating mirror arranged at the internal space and configured to concentrate the extreme ultraviolet light, a debris shield provided with a first opening through which the extreme ultraviolet light passes from the plasma generation region toward the light concentrating mirror and a second opening, and surrounding the plasma generation region, a gas supply port provided at the chamber and configured to supply a gas to the internal space, and an exhaust port configured to exhaust a gas in a space surrounded by the debris shield. At least a part of the second opening is provided at a position symmetrical to at least a part of the first opening with reference to a plane including a trajectory of the laser light and a trajectory of the droplet. The gas at the internal space flows into the space through the first opening and the second opening.

An electronic device manufacturing method according to an aspect of the present disclosure includes inspecting a defect of a mask by irradiating the mask with extreme ultraviolet light generated using an extreme ultraviolet light generation apparatus, selecting the mask using a result of the inspection, and exposing and transferring a pattern formed on the selected mask onto a photosensitive substrate. Here, the extreme ultraviolet light generation apparatus includes a chamber in which a target substance supplied to a plasma generation region at an internal space thereof is irradiated with laser light to generate the extreme ultraviolet light, a target supply unit configured to supply a droplet of the target substance toward the plasma generation region, a light concentrating mirror arranged at the internal space and configured to concentrate the extreme ultraviolet light, a debris shield provided with a first opening through which the extreme ultraviolet light passes from the plasma generation region toward the light concentrating mirror and a second opening, and surrounding the plasma generation region, a gas supply port provided at the chamber and configured to supply a gas to the internal space, and an exhaust port configured to exhaust a gas in a space surrounded by the debris shield. At least a part of the second opening is provided at a position symmetrical to at least a part of the first opening with reference to a plane including a trajectory of the laser light and a trajectory of the droplet. The gas at the internal space flows into the space through the first opening and the second opening.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire electronic device manufacturing apparatus different from the electronic device manufacturing apparatus shown in FIG. 1.

FIG. 3 is a schematic view showing a schematic configuration example of the entire extreme ultraviolet light generation apparatus of a comparative example.

FIG. 4 is a schematic view showing the extreme ultraviolet light generation apparatus in a cross section perpendicular to the trajectory of a droplet in the comparative example.

FIG. 5 is a schematic view showing the extreme ultraviolet light generation apparatus in a cross section along the trajectory of the droplet in the comparative example.

FIG. 6 is a view showing the traveling of the droplet and the flow of a gas in a debris shield.

FIG. 7 is a view showing the traveling of the droplet and the flow of the gas in the debris shield immediately after the droplet is irradiated with laser light.

FIG. 8 is a schematic view showing a chamber of the extreme ultraviolet light generation apparatus of a first embodiment in a cross section perpendicular to the longitudinal direction of the debris shield.

FIG. 9 is a schematic view showing the configuration of a part of the chamber of the extreme ultraviolet light generation apparatus of the first embodiment in a cross section along the longitudinal direction of the debris shield.

FIG. 10 is a schematic view showing the chamber of the extreme ultraviolet light generation apparatus of a second embodiment in a cross section along the longitudinal direction of the debris shield.

FIG. 11 is a schematic view showing the configuration of a part of the chamber of the extreme ultraviolet light generation apparatus of the second embodiment in a cross section perpendicular the longitudinal direction of the debris shield.

### DESCRIPTION OF EMBODIMENTS

1. Overview
2. Description of electronic device manufacturing apparatus
3. Description of extreme ultraviolet light generation apparatus of comparative example
   3.1 Configuration
   3.2 Operation
   3.3 Problem
4. Description of extreme ultraviolet light generation apparatus of first embodiment
   4.1 Configuration
   4.2 Operation
   4.3 Effect
5. Description of extreme ultraviolet light generation apparatus of second embodiment
   5.1 Configuration
   5.2 Operation
   5.3 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview

Embodiments of the present disclosure relate to an extreme ultraviolet light generation apparatus generating light having a wavelength of extreme ultraviolet (EUV) and an electronic device manufacturing apparatus. In the following, extreme ultraviolet light is referred to as EUV light in some cases.

### 2. Description of Electronic Device Manufacturing Apparatus

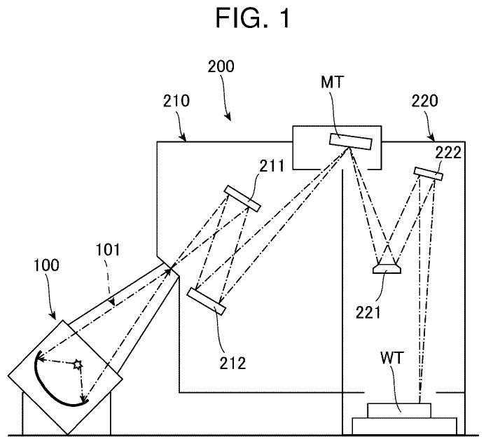

FIG. 1 is a schematic view showing a schematic configuration example of an entire electronic device manufacturing apparatus. The electronic device manufacturing apparatus shown in FIG. 1 includes an EUV light generation apparatus 100 and an exposure apparatus 200. The exposure apparatus 200 includes a mask irradiation unit 210 including a plurality of mirrors 211, 212 that configure a reflection optical system, and a workpiece irradiation unit 220 including a plurality of mirrors 221, 222 that configure a reflection optical system different from the reflection optical system of the mask irradiation unit 210. The mask irradiation unit 210 illuminates, via the mirrors 211, 212, a mask pattern of a mask table MT with EUV light 101 incident from the EUV light generation apparatus 100. The workpiece irradiation unit 220 images the EUV light 101 reflected by the mask table MT onto a workpiece (not shown) arranged on a workpiece table WT via the mirrors 221, 222. The workpiece is a photosensitive substrate such as a semiconductor wafer on which photoresist is applied. The exposure apparatus 200 synchronously translates the mask table MT and the workpiece table WT to expose the workpiece to the EUV light 101 reflecting the mask pattern. Through the exposure process as described above, a device pattern is transferred onto the semiconductor wafer, whereby a semiconductor device can be manufactured.

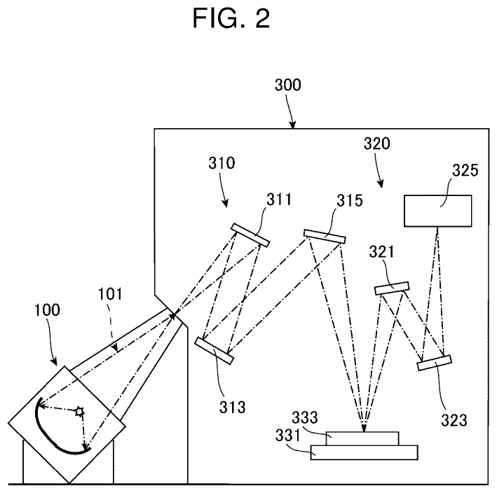

FIG. 2 is a schematic view showing a schematic configuration example of an entire electronic device manufacturing apparatus different from the electronic device manufacturing apparatus shown in FIG. 1. The electronic device manufacturing apparatus shown in FIG. 2 includes the EUV light generation apparatus 100 and an inspection apparatus 300. The inspection apparatus 300 includes an illumination optical system 310 including a plurality of mirrors 311, 313, 315 that configure a reflection optical system, and a detection optical system 320 including a detector 325 and a plurality of mirrors 321, 322 that configure a reflection optical system different from the reflection optical system of the illumination optical system 310. The illumination optical system 310 reflects, with the mirrors 311, 313, 315, the EUV light 101 incident from the EUV light generation apparatus 100 to illuminate a mask 333 placed on a mask stage 331. The mask 333 includes a mask blanks before a pattern is formed. The detection optical system 320 reflects, with the mirrors 321, 323, the EUV light 101 reflecting the pattern from the mask 333 and forms an image on a light receiving surface of the detector 325. The detector 325 having received the EUV light 101 acquires an image of the mask 333. The detector 325 is, for example, a time delay integration (TDI) camera. A defect of the mask 333 is inspected based on the image of the mask 333 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 200.

### 3. Description of Extreme Ultraviolet Light Generation Apparatus of Comparative Example

### 3.1 Configuration

The EUV light generation apparatus 100 of a comparative example will be described. The comparative example of the present disclosure is an example recognized by the applicant as known only by the applicant, and is not a publicly known example admitted by the applicant. Further, the following description will be given with reference to the EUV light generation apparatus 100 that outputs the EUV light 101 to the exposure apparatus 200 as a subsequent process apparatus as shown in FIG. 1. Here, the EUV light generation apparatus 100 that outputs the EUV light 101 to the inspection apparatus 300 as a subsequent process apparatus as shown in FIG. 2 can obtain the same operation and effect.

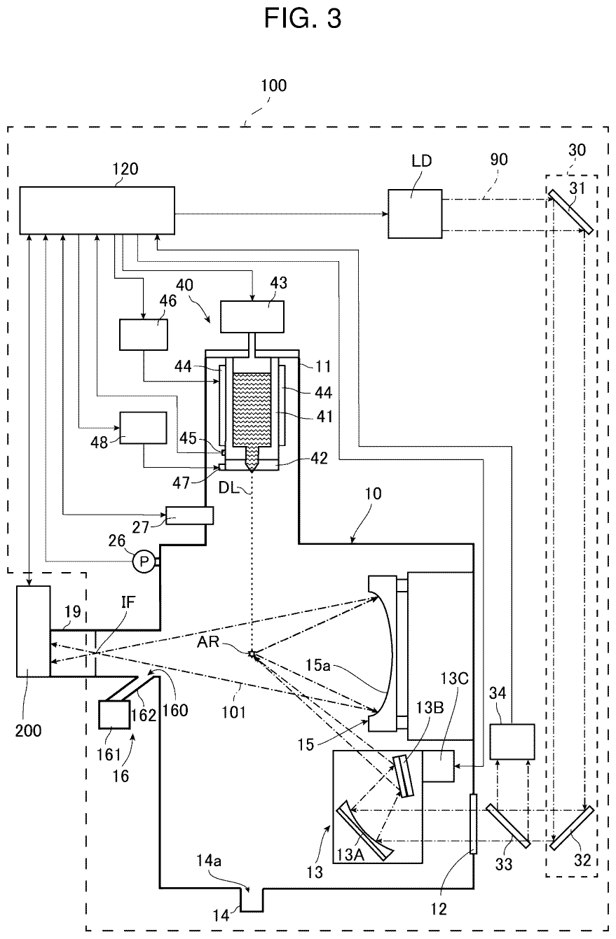

FIG. 3 is a schematic view showing a schematic configuration example of the entire EUV light generation apparatus 100 of the present example. As shown in FIG. 3, the EUV light generation apparatus 100 includes a chamber 10, a laser device LD, a laser light delivery optical system 121, and a processor 120 as a main configuration.

The chamber 10 is a sealable container. The chamber 10 includes a sub-chamber 11, and a target supply unit 40 is attached to the sub-chamber 11 to penetrate a wall of the sub-chamber 11. The target supply unit 40 includes a tank 41, a nozzle 42, and a pressure regulator 43 to supply a droplet DL to the internal space of the chamber 10. The droplet DL is sometimes referred to as a droplet target or a target.

The tank 41 stores therein a target substance which becomes the droplet DL. The target substance contains tin. The inside of the tank 41 is in communication with the pressure regulator 43 which adjusts the pressure in the tank 41. A heater 44 and a temperature sensor 45 are attached to the tank 41. The heater 44 heats the tank 41 with a current applied from a heater power source 46. Through the heating, the target substance in the tank 41 melts. The temperature sensor 45 measures, via the tank 41, the temperature of the target substance in the tank 41. The pressure regulator 43, the temperature sensor 45, and the heater power source 46 are electrically connected to the processor 120.

The nozzle 42 is attached to the tank 41 and outputs the target substance. A piezoelectric element 47 is attached to the nozzle 42. The piezoelectric element 47 is electrically connected to a piezoelectric power source 48 and is driven by a voltage applied from the piezoelectric power source 48. The piezoelectric power source 48 is electrically connected to the processor 120. The target substance output from the nozzle 42 is formed into the droplet DL through operation of the piezoelectric element 47.

The chamber 10 includes a target collection unit 14. The target collection unit 14 is a box body attached to the chamber 10 and communicates with the internal space of the chamber 10 through an opening 14a formed at the chamber 10. The opening 14a is arranged directly below the nozzle 42. The target collection unit 14 is a drain tank to collect any unnecessary droplet DL having passed through the opening 14a and reaching the target collection unit 14.

The chamber 10 is provided with a window 12 through which light from the outside is transmitted, and pulse laser light 90 output from the laser device LD is transmitted through the window 12.

Further, a laser light concentrating optical system 13 is arranged at the internal space of the chamber 10. The laser light concentrating optical system 13 includes a laser light concentrating mirror 13A and a high reflection mirror 13B. The laser light concentrating mirror 13A reflects and concentrates the laser light 90 having transmitted through the window 12. The high reflection mirror 13B reflects the laser light 90 concentrated by the laser light concentrating mirror 13A. Positions of the laser light concentrating mirror 13A and the high reflection mirror 13B are adjusted by a laser light manipulator 13C so that a concentration position of the laser light 90 at the internal space of the chamber 10 coincides with a position specified by the processor 120. The light concentration position is adjusted to be a position directly below the nozzle 42, and when the target substance is irradiated with the laser light 90 at the light concentration position, plasma is generated from the target substance, and the EUV light 101 is radiated from the plasma. The region in which plasma is generated is sometimes referred to as a plasma generation region AR. The plasma generation region AR is a region having a radius of, for example, 40 mm about a plasma point and is located at the internal space of the chamber 10.

For example, an EUV light concentrating mirror 15 having a spheroidal reflection surface 15a is arranged at the internal space of the chamber 10. The EUV light concentrating mirror 15 includes, for example, a multilayer film in which silicon layers and molybdenum layers are alternately laminated, and reflects the EUV light 101 by the multilayer film. The EUV light concentrating mirror 15 is provided at a position not overlapping the optical path of the laser light 90 at the internal space of the chamber 10. The reflection surface 15a reflects the EUV light 101 radiated from the plasma in the plasma generation region AR. The reflection surface 15a has a first focal point and a second focal point. The reflection surface 15a may be arranged such that, for example, the first focal point is located in the plasma generation region AR and the second focal point is located at an intermediate focal point IF.

The EUV light generation apparatus 100 includes a connection portion 19 providing communication between the internal space of the chamber 10 and the internal space of the exposure apparatus 200. A wall in which an aperture is formed is arranged in the connection portion 19. The wall is preferably arranged such that the aperture is located at the second focal point. The connection portion 19 is an outlet port of the EUV light 101 in the chamber 10, and the EUV light 101 is output from the connection portion 19 and enters the exposure apparatus 200.

A first etching gas supply unit 16 is connected to the chamber 10. The first etching gas supply unit 16 includes a first gas supply port 160. The etching gas contains a hydrogen gas, and the etching gas of the present example is a hydrogen gas having a hydrogen concentration of 100% in effect. Therefore, in the present example, the first etching gas supply unit 16 further includes a hydrogen tank 161 and a gas pipe 162. The first etching gas supply unit 16 supplies the hydrogen gas in the hydrogen tank 161 to the reflection surface 15a of the EUV light concentrating mirror 15 from the first gas supply port 160 via the gas pipe 162. The first etching gas supply unit 16 is controlled by the processor 120. A gas flow rate adjustment unit (not shown) being a valve may be provided at the gas pipe 162. For example, when the gas flow rate adjustment unit is provided, the processor 120 controls the gas flow rate adjustment unit to adjust the flow rate of the etching gas to be supplied. Here, the etching gas may be, for example, a balance gas having a hydrogen gas concentration of about 38. In this case, the balance gas includes, for example, a nitrogen (N₂) gas or an argon (Ar) gas.

Further, the EUV light generation apparatus 100 includes a pressure sensor 26 and a detection unit 27 as a target sensor. The pressure sensor 26 and the detection unit 27 are attached to the chamber 10 and are electrically connected to the processor 120. The pressure sensor 26 measures the pressure at the internal space of the chamber 10 and outputs a signal indicating the pressure to the processor 120.

The detection unit 27 has, for example, an imaging function, and detects the presence, trajectory, position, velocity, and the like of the droplet DL output from a nozzle hole of the nozzle 42 in accordance with an instruction from the processor 120. The detection unit 27 may be arranged inside the chamber 10, or may be arranged outside the chamber 10 and detect the droplet DL through a window (not shown) arranged on a wall of the chamber 10. The detection unit 27 includes a light receiving optical system (not shown) and an imaging unit (not shown) such as a charge-coupled device (CCD) or a photodiode. In order to improve the detection accuracy of the droplet DL, the light receiving optical system forms an image of the trajectory of the droplet DL and the periphery thereof on a light receiving surface of the imaging unit. When the droplet DL passes through a light concentration region of a light source (not shown) arranged to improve contrast in the field of view of the detection unit 27, the imaging unit detects a change of the light passing through the trajectory of the droplet DL and the periphery thereof. The imaging unit converts the detected light change into an electric signal. The electric signal may include image data of the droplet DL. The imaging unit outputs the electric signal to the processor 120.

The laser device LD includes a master oscillator being a light source to perform burst operation. The master oscillator outputs the pulse laser light 90 in a burst-on duration. The master oscillator is, for example, a solid-state laser device that excites a YAG Y crystal to which niobium (Nb) or ytterbium (Yb) is added, or a laser device that outputs the laser light 90 by exciting a gas in which helium, nitrogen, or the like is mixed in a carbon dioxide gas through electric discharge. Alternatively, the master oscillator may be a quantum cascade laser device. The master oscillator may output the pulse laser light 90 by a Q switch system. Further, the master oscillator may include an optical switch, a polarizer, and the like. The laser device LD may include an amplifier that amplifies the laser light 90 output from the master oscillator. The burst operation is operation of repeatedly performing burst-on in which continuous pulse laser light 90 is output at a predetermined repetition frequency and burst-off in which output of the laser light 90 is stopped.

The travel direction of the laser light 90 output from the laser device LD is adjusted by the laser light delivery optical system 30. The laser light delivery optical system 30 includes a plurality of mirrors 31, 32 for adjusting the travel direction of the laser light 90. The position of at least one of the mirrors 31, 32 is adjusted by an actuator (not shown). Owing to that the position of at least one of the mirrors 31, 32 is adjusted, the laser light 90 can appropriately propagate to the internal space of the chamber 10 through the window 12.

Between the mirror 32 and the window 12, a beam splitter 33 is provided. The beam splitter 33 transmits most of the laser light 90 reflected by the mirror 32 and reflects a part of the laser light 90. A laser light measurement instrument 34 is provided ahead in the travel direction of the laser light 90 reflected by the beam splitter 33. The laser light t measurement instrument 34 includes a light receiving element, measures the power of the received laser light 90, and outputs a signal related to the power of the laser light 90. The laser light measurement instrument 34 is electrically connected to the processor 120, and a signal related to the power of the laser light 90 is input to the processor 120.

The processor 120 of the present disclosure is a processing device including a storage device in which a control program is stored and a central processing unit (CPU) that executes the control program. The processor 120 is specifically configured or programmed to perform various processes included in the present disclosure and controls the entire EUV light generation apparatus 100. The processor 120 receives a signal related to the pressure at the internal space of the chamber 10 measured by the pressure sensor 26, a signal related to image data of the droplet DL captured by the detection unit 27, a burst signal instructing the burst operation from the exposure apparatus 200, and the like. The processor 120 processes the various signals, and may control, for example, timing at which the droplet DL is output, the output direction of the droplet DL, and the like. Further, the processor 120 may control the output timing of the laser device LD, the travel direction and the concentration position of the laser light 90, and the like. The above-described various kinds of control are merely examples, and as will be described later, other control may be added as necessary.

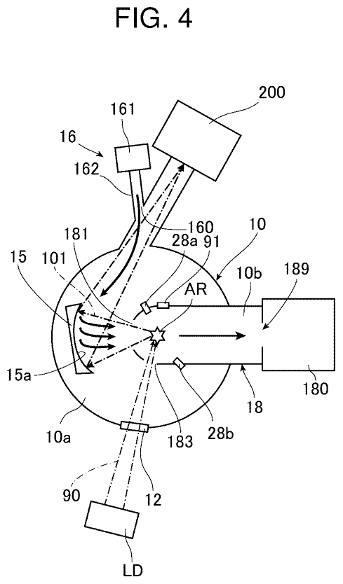

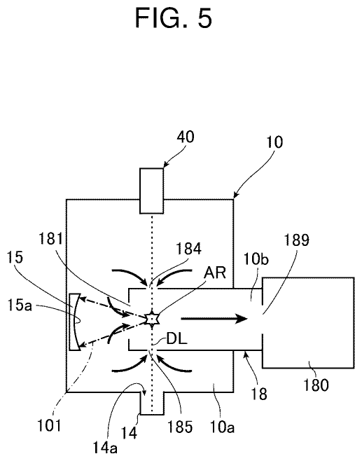

FIG. 4 is a schematic view showing the EUV light generation apparatus 100 in a cross section perpendicular to the trajectory of the droplet DL in the comparative example, and FIG. 5 is a schematic view showing the EUV light generation apparatus 100 in a cross section along the trajectory of the droplet DL in the comparative example. In FIGS. 4 and 5, for simplification of illustration, the laser light concentrating mirror 13A and the high reflection mirror 13B are omitted, and a travel path of the laser light 90 from the window 12 to the plasma generation region AR is shown in a simple manner.

The EUV light generation apparatus 100 includes a cylindrical debris shield 18 extending from the internal space of the chamber 10 to the external space of the chamber 10. The inner diameter of the debris shield 18 is preferably 90 mm or more and 160 mm or less. In FIGS. 4 and 5, among the internal space of the chamber 10, a space outside the debris shield 18 is indicated as a first space 10a and a space inside the debris shield 18 is indicated as a second space 10b. In FIG. 3, the debris shield 18 is omitted.

The debris shield 18 surrounds the plasma generation region AR. That is, the plasma generation region AR is located in the second space 10b. The debris shield 18 is a partition wall that suppresses scattering, to the first space 10a, of debris such as a target substance scattered from the plasma generation region AR. A first opening 181 is provided at one end of the debris shield 18 located at the internal space of the chamber 10, and a gas exhaust port 189 is provided at the other end of the debris shield 18 located outside the chamber 10. The gas exhaust port 189 is connected to an exhaust device 180 including an exhaust pump. Therefore, at least a part of the gas in the first space 10a flows from the first opening 181 into the second space 10b and is discharged from the gas exhaust port 189. The debris shield 18 has a cylindrical shape in which the longitudinal direction extends from the first opening 181 toward the gas exhaust port 189, that is, a cylindrical shape in which the longitudinal direction extends in the gas exhaust direction. Here, the shape of the cross section perpendicular to the longitudinal direction of the debris shield 18 may be circular or non-circular. Further, the thickness of the debris shield 18 may not be constant.

The first opening 181 is provided between the plasma generation region AR and the EUV light concentrating mirror 15. Accordingly, the EUV light 101 generated in the plasma generation region AR passes through the first opening 181 toward the EUV light concentrating mirror 15. The EUV light concentrating mirror 15 reflects the EUV light 101 incident from the first opening 181 toward the intermediate focal point IF located in a direction different from the incident direction of the EUV light 101.

Further, a laser light inlet opening 183, a droplet supply opening 184, and a droplet discharge opening 185 are provided in the side wall of the debris shield 18. The laser light inlet opening 183 is provided on the optical path of the laser light 90 toward the plasma generation region AR at the internal space of the chamber 10, and the laser light 90 enters the plasma generation region AR from the first space 10a through the laser light inlet opening 183. A laser damper 91 is provided on the opposite side of the laser light inlet opening 183 with respect to the plasma generation region AR at the debris shield 18. The laser damper 91 is irradiated with the laser light 90 that has not been radiated to the droplet DL, and changes the optical energy of the laser light 90 into heat. The droplet supply opening 184 and the droplet discharge opening 185 are provided on the trajectory of the droplet DL and face each other. The droplet DL is supplied from the target supply unit 40 to the plasma generation region AR through the droplet supply opening 184. The droplet discharge opening 185 faces the opening 14a connected to the target collection unit 14, and the droplet DL that has passed through the plasma generation region AR enters the target collection unit 14 through the droplet discharge opening 185. In the present example, the areas of the droplet supply opening 184 and the droplet discharge opening 185 are substantially the same and are each larger than the area of the laser light inlet opening 183. The area of the first opening 181 is larger than the area of any of the other openings provided in the debris shield 18 except the gas exhaust port 189.

In the present example, the debris shield 18 is provided with a plurality of sensors 28a, 28b for monitoring the state in the second space 10b. For example, the sensors 28a, 28b monitor the state of the plasma generation region AR or the vicinity thereof, and may include a target sensor for detecting at least one of the presence, trajectory, position, and velocity of the droplet DL, or may include a sensor for detecting an emission point of the EUV light 101. The sensors 28a, 28b may include an image sensor or an optical sensor, and an optical system that forms an image at the plasma generation region AR or the vicinity thereof on the image sensor or the optical sensor. Further, although not particularly shown, a light source that illuminates the plasma generation region AR with visible light may be arranged. In FIG. 3, the sensors 28a, 28b are omitted.

The first etching gas supply unit 16 supplies, through the gas pipe 162, the etching gas in the hydrogen tank 161 to the first space 10a at the internal space of the chamber 10 from the first gas supply port 160. In the present example, the etching gas is supplied toward the reflection surface 15a of the EUV light concentrating mirror 15. The flow rate of the etching gas supplied from the first etching gas supply unit 16 to the first space 10a is, for example, 10 l/min or more and 100 l/min or less. Here, the flow rate of the etching gas may be represented by nlm which represents the volume of the etching gas flowing per minute converted to that at 0° C. and 1 atm. Since the area of the first opening 181 is larger than the area of any of the other openings provided in the debris shield 18 except the gas exhaust port 189 as described above, the etching gas supplied to the first space 10a flows into the second space 10b mainly through the first opening 181 as indicated by arrows in FIGS. 4 and 5. However, the etching gas may also flow into the second space 10b through the laser light inlet opening 183, the droplet supply opening 184, and the droplet discharge opening 185.

Since the target substance contains tin as described above, tin fine particles and tin charged particles are generated when the target substance is turned into plasma in the plasma generation region AR by being irradiated with the laser light 90. Further, hydrogen contained in the etching gas supplied from the first etching gas supply unit 16 to the internal space of the chamber 10 becomes hydrogen radicals due to the energy of the EUV light 101. Tin constituting the fine particles and the charged particles reacts with hydrogen radicals. When tin reacts with hydrogen radicals, stannane (SnH₄) at gas room temperature is generated.

When the target substance is turned into plasma in the plasma generation region AR, the residual gas as an exhaust gas is generated in the second space 10b. The residual gas contains tin fine particles and tin charged particles generated through the plasma generation from the target substance, stannane generated through the reaction of the tin fine particles and tin charged particles with the etching gas, and an unreacted etching gas. Some of the charged particles are neutralized in the second space 10b, and the residual gas contains the neutralized charged particles as well. The gas exhaust port 189 exhausts the etching gas having flowed from the first space 10a to the second space 10b together with the residual gas to the outside of the chamber 10. Specifically, the gas exhaust port 189 exhausts the etching gas and the residual gas to the exhaust device 180 by suction of the exhaust device 180.

### 3.2 Operation

Next, operation of the EUV light generation apparatus 100 of the comparative example will be described.

In the EUV light generation apparatus 100, for example, at the time of new installation or maintenance or the like, atmospheric air at the internal space of the chamber 10 is exhausted. At this time, purging and exhausting of the internal space of the chamber 10 may be repeated for exhausting atmospheric components. For example, an inert gas such as nitrogen or argon is preferably used for the purge gas. Thereafter, when the pressure at the internal space of the chamber 10 becomes equal to or lower than a predetermined pressure, the processor 120 starts introducing the etching gas into the first space 10a of the chamber 10 through the first gas supply port 160 of the first etching gas supply unit 16. At this time, the processor 120 may control the supply gas flow rate adjustment unit and the exhaust device 180 so that the pressure at the internal space of the chamber 10 is maintained at the predetermined pressure. Thereafter, the processor 120 waits until a predetermined time elapses from the start of introduction of the etching gas.

Further, the processor 120 causes the gas at the internal space of the chamber 10 to be exhausted from the gas exhaust port 189 by the exhaust device 180, and maintains the pressure at the internal space of the chamber substantially constant based on the signal indicating the pressure at the internal space of chamber 10 measured by the pressure sensor 26.

In order to heat and maintain the target substance in the tank 41 to and at a predetermined temperature equal to or higher than the melting point, the processor 120 causes the heater power source 46 to supply a current to the heater 44 to increase temperature of the heater 44. In this case, the processor 120 controls the temperature of the target substance to the predetermined temperature by adjusting a value of the current to be supplied from the heater power source 46 to the heater 44 based on an output from the temperature sensor 45. When the target substance is tin, the predetermined temperature is equal to or higher than 231.93° C. being the melting point of tin and, for example, is 240° C. or higher and 290° C. or lower. Thus, the preparation for outputting the droplet DL is completed.

When the preparation is completed, the processor 120 causes the pressure regulator 43 to supply the inert gas from a gas supply source (not shown) to the tank 41 and to adjust the pressure in the tank 41 so that the molten target substance is output through the nozzle hole of the nozzle 42 at a predetermined velocity. Under this pressure, the target substance is output into the first space 10a of the chamber 10 through the nozzle hole of the nozzle 42. The target substance output through the nozzle hole may be in the form of jet. At this time, the processor 120 causes the piezoelectric power source 48 to apply a voltage having a predetermined waveform to the piezoelectric element 47 to generate the droplet DL. The piezoelectric power source 48 applies the voltage so that the waveform of the voltage becomes, for example, a sine wave, a rectangular wave, or a sawtooth wave. Vibration of the piezoelectric element 47 propagates through the nozzle 42 to the target substance to be output through the nozzle hole of the nozzle 42. The target substance is divided at a predetermined cycle by the vibration into liquid droplets DL. The diameter of the droplet DL is approximately 10 μm or more and 30 μm or less.

When the droplet DL of the target substance is output, the droplet passes through the droplet supply opening 184 and travels to the plasma generation region AR. The detection unit 27 detects the passage timing of the droplet DL passing through a predetermined position in the second space 10b of the chamber 10. The processor 120 outputs a trigger signal to control the timing of outputting the laser light 90 from the laser device LD based on the signal from the detection unit 27 so that the droplet DL is irradiated with the laser light 90. The trigger signal output from the processor 120 is input to the laser device LD. When the trigger signal is input, the laser device LD outputs the pulse laser light 90.

The output laser light 90 enters the laser light concentrating optical system 13 via the laser light delivery optical system 30 and the window 12. At this time, the laser light 90 reflected by the beam splitter 33 is received by the laser light measurement instrument 34, and the power thereof is measured. The laser light measurement instrument 34 outputs a signal related to the measured power of the laser light 90 to the processor 120. The processor 120 controls the laser device LD based on the signal input from the laser light measurement instrument 34, so that the laser device LD outputs the laser light 90 having a desired power. The laser light 90 travels from the laser light concentrating optical system 13 toward the plasma generation region AR through the laser light inlet opening 183. Then, the droplet DL is irradiated with the laser light 90 in the plasma generation region AR. At this time, the processor 120 controls the laser light manipulator 13C of the laser light concentrating optical system 13 so that the laser light 90 is concentrated in the plasma generation region AR. The processor 120 controls the timing of outputting the laser light 90 from the laser device LD based on the signal from the detection unit 27 so that the droplet DL is irradiated with the laser light 90. Thus, the droplet DL is irradiated in the plasma generation region AR with the laser light 90 concentrated by the laser light concentrating mirror 13A. Plasma is generated by the irradiation, and light including the EUV light 101 is radiated from the plasma.

Among the light including the EUV light 101 generated in the plasma generation region AR, the EUV light 101 travels to the EUV light concentrating mirror 15 after passing through the first opening 181, is concentrated at the intermediate focal point IF by the EUV light concentrating mirror 15, and then, enters the exposure apparatus 200 from the connection portion 19.

Hydrogen contained in the etching gas supplied from the first gas supply port 160 becomes hydrogen radicals due to the energy of the EUV light 101. Therefore, when tin is deposited on the reflection surface 15a of the EUV light concentrating mirror an inner circumferential surface of the debris shield 18, the tin reacts with hydrogen radicals to become stannane, and is removed from the reflection surface 15a or the inner circumferential surface of the debris shield 18. The etching gas and the stannane in the first space 10a mainly flow into the second space 10b from the first opening 181. The exhaust device 180 suctions the etching gas together with the residual gas in the second space 10b through the gas exhaust port 189. Accordingly, the gas in the second space 10b is exhausted to the outside of the chamber 10. The gas suctioned by the exhaust device 180 is subjected to predetermined exhaust treatment such as detoxification.

### 3.3 Problem

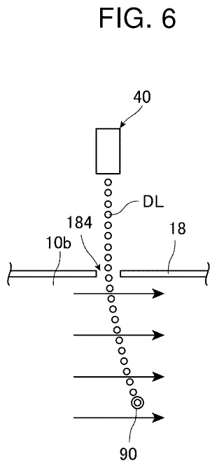

FIG. 6 is a view showing the traveling of the droplet DL and the flow of the gas in the second space 10b. In FIG. 6, the chamber 10 is omitted, and the flow of the gas is indicated by arrows. As shown in FIG. 6, the trajectory of the droplet DL is slightly changed by the flow of the gas flowing in from the first opening 181 toward the gas exhaust port 189. Then, the detection unit 27, the sensors 28a, 28b, and the like detect the trajectory of the droplet DL, and the processor 120 controls the laser light manipulator 13C to adjust the positions of the laser light concentrating mirror 13A and the high reflection mirror 13B so that the laser light 90 is radiated onto the detected trajectory of the droplet DL. Therefore, the droplet DL is irradiated with the laser light 90.

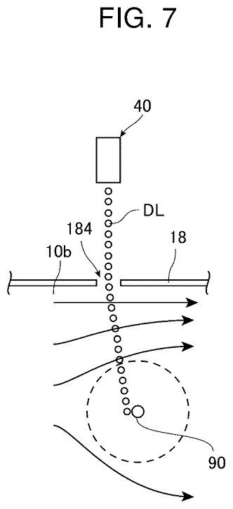

FIG. 7 is a view showing the traveling of the droplet DL and the flow of the gas in the second space 10b immediately after the droplet DL is irradiated with the laser light 90. When the droplet DL is irradiated with the laser light 90, the gas density in the plasma generation region AR and the periphery of the plasma generation region AR indicated by a broken line is reduced due to heat and shock waves generated from the droplet DL. This temporarily changes the flow of the gas. Due to the change in the flow of the gas, the trajectory of the droplet DL may temporarily deviate from the irradiation position of the laser light 90, and the droplet DL may not be irradiated with the laser light 90. Therefore, the output of the EUV light 101 may become unstable.

Therefore, in the following embodiments, the EUV light generation apparatus 100 capable of suppressing the output of the EUV light 101 from becoming unstable is exemplified.

### 4. Description of Extreme Ultraviolet Light Generation Apparatus of First Embodiment

The configuration of the EUV light generation apparatus 100 of a first embodiment will be described. Any component same as that described above is denoted by an identical reference sign, and duplicate description thereof is omitted unless specific description is needed.

### 4.1 Configuration

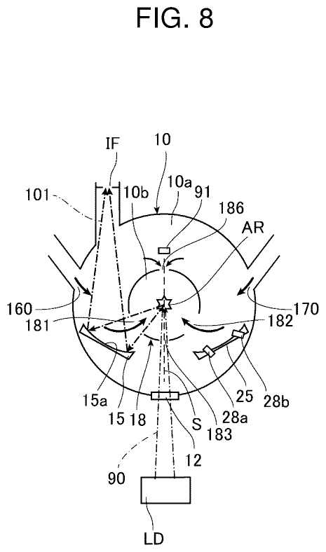

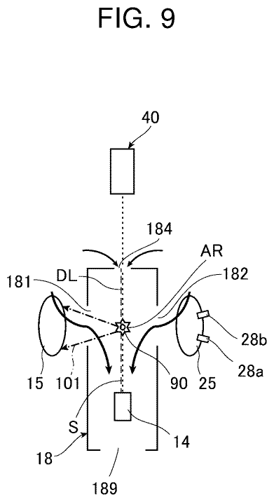

FIG. 8 is a schematic view showing the chamber 10 of the EUV light generation apparatus 100 of the present embodiment in a cross section perpendicular to the longitudinal direction of the debris shield 18, and FIG. 9 is a schematic view showing the configuration of a part of the inside of the chamber 10 in a cross section along the longitudinal direction of the debris shield 18.

As shown in FIGS. 8 and 9, in the present embodiment, the EUV light concentrating mirror 15 is arranged on a lateral side in the radial direction of the cylindrical debris shield 18. Accordingly, the first opening 181 is provided in the side wall of the debris shield 18. Further, in the present embodiment, the first gas supply port 160 is provided in the chamber 10 so that the etching gas is supplied from the EUV light concentrating mirror 15 side, with reference to the debris shield 18, to the internal space of the chamber 10. In the present embodiment as well, the etching gas is supplied from the first gas supply port 160 toward the reflection surface 15a of the EUV light concentrating mirror 15. At least a part of the etching gas supplied from the first gas supply port 160 is guided to the first opening 181 by the EUV light concentrating mirror 15.

Further, in the present embodiment, the droplet supply opening 184 is provided at an end part in the longitudinal direction of the debris shield 18. Therefore, the target supply unit 40 supplies the droplet DL from the end part of the debris shield 18 to the inside of the second space 10b through the droplet supply opening 184 along the longitudinal direction of the debris shield 18. Therefore, in the present embodiment, the target collection unit 14 is provided in the second space 10b.

In the present embodiment as well, as in the comparative example, the laser light 90 is radiated to the plasma generation region AR through the laser light inlet opening 183. In the present embodiment, a laser light outlet opening 186 is provided in the debris shield 18 on the opposite side of the laser light inlet opening 183 with respect to the plasma generation region AR. Further, the laser damper 91 is provided at a position where the laser light passes through the laser light outlet opening 186 from the laser light inlet opening 183. Therefore, the laser light 90 that has not been radiated to the droplet DL is radiated to the laser damper 91 through the laser light outlet opening 186, and is photothermally converted.

Since the laser light 90 is radiated non-parallel to the trajectory of the droplet DL, a plane S including the trajectory of the laser light 90 and the trajectory of the droplet DL can be defined. In FIG. 9, the plane S is shown slightly shifted from the trajectory of the droplet DL. The plane S is perpendicular to the paper surfaces of FIGS. 8 and 9. The first gas supply port 160 is located on the same side, with respect to the plane S, as the side where the first opening 181 is located.

In the present embodiment, a second gas supply port 170 is provided in the chamber 10 on the opposite side of the first gas supply port 160 with respect to the debris shield 18. The first gas supply port 160 and the second gas supply port 170 configure a gas supply port for supplying the etching gas to the internal space of the chamber 10. Although not particularly shown, a gas pipe similar to the gas pipe 162 is connected to the second gas supply port 170, and a hydrogen tank similar to the hydrogen tank 161 is connected to the gas pipe. Therefore, the etching gas is supplied to the first space 10a from the second gas supply port 170. It is preferable that at least a part of the second gas supply port 170 is provided at a position symmetrical to at least a part of the first gas supply port 160 with respect to the plane S. It is preferable that the same amount of the etching gas is supplied from the first gas supply port 160 and the second gas supply port 170, respectively. Further, it is preferable that the first gas supply port 160 and the second gas supply port 170 have the same area from the viewpoint that the flow velocities of the etching gas supplied from the respective supply ports can be brought close to each other when the same amount of the etching gas is supplied from the respective supply ports. Further, it is preferable that the first gas supply port 160 and the second gas supply port 170 have the same shape from the viewpoint that the flow states of the gas flowing into the first space 10a respectively from the first gas supply port 160 and the second gas supply port 170 can be brought close to each other. Further, it is preferable that the first gas supply port 160 and the second gas supply port 170 overlap each other by 95% or more in the direction perpendicular to the plane S from the viewpoint of enhancing the symmetry of the first gas supply port 160 and the second gas supply port 170 with respect to the plane S and enhancing the symmetry of the flow of the gas supplied respectively from the first gas supply port 160 and the flow of the gas supplied from the second gas supply port 170.

Further, in the present embodiment, a second opening 182 is provided in the debris shield 18. At least a part of the second opening 182 is provided at a position symmetrical to at least a part of the first opening 181 with respect to the plane S. Accordingly, the second opening 182 and the second gas supply port 170 are provided on the same side with respect to the plane S. Therefore, at least a part of the etching gas supplied from the second gas supply port 170 flows into the second space 10b from the second opening 182.

It is preferable that the first opening 181 and the second opening 182 have the same area from the viewpoint that the amounts of the gas flowing into the second space 10b respectively from the first opening 181 and the second opening 182 can be brought close to each other. Further, it is preferable that the first opening 181 and the second opening 182 have the same shape from the viewpoint that the flow states of the gas flowing into the second space 10b respectively from the first opening 181 and the second opening 182 can be brought close to each other. Further, it is preferable that each of the first opening 181 and the second opening 182 has a larger area than any of the other openings provided in the debris shield 18 from the viewpoint that the flow of the gas flowing in respectively from the first opening 181 and the second opening 182 may be dominant with respect to the effect on the flow of the gas toward the gas exhaust port 189 in the second space 10b. Further, it is preferable that the first opening 181 and the second opening 182 overlap each other by 95% or more in the direction perpendicular to the plane S from the viewpoint of enhancing the symmetry of the first opening 181 and the second opening 182 with respect to the plane S and enhancing the symmetry of the gas flowing in from the first opening 181 into the second space 10b and the gas flowing in from the second opening 182 into the second space 10b.

In the present embodiment, an auxiliary plate 25 is provided on a lateral side of the debris shield 18 on the side of the second opening 182. The auxiliary plate 25 guides the etching gas supplied from the second gas supply port 170 to the second opening 182. It is preferable that at least a part of the auxiliary plate 25 is provided at a position symmetrical to the EUV light concentrating mirror 15 with respect to the plane S from the viewpoint that the amounts of the gas flowing into the second space 10b respectively from the first opening 181 and the second opening 182 can be brought close to each other. The auxiliary plate 25 of the present embodiment has the same shape as the EUV light concentrating mirror 15, and is arranged symmetrically with respect to the plane S. Therefore, the auxiliary plate 25 has a concave shape recessed in a direction symmetrical to the direction in which the EUV light concentrating mirror 15 is recessed with respect to the plane S. Here, when the auxiliary plate 25 does not have the same shape as the EUV light concentrating mirror 15, it is preferable that the auxiliary plate 25 has a concave shape recessed in a direction symmetrical with the direction in which the EUV light concentrating mirror 15 is recessed with respect to the plane S, but may be a flat plate.

In the present embodiment, the sensors 28a, 28b are attached to the auxiliary plate 25. The sensors 28a, 28b observe the state in the second space 10b through the second opening 182.

### 4.2 Operation

In the EUV light generation apparatus 100 of the present embodiment, the etching gas is supplied from the first gas supply port 160 and the second gas supply port 170 in the same period as the period in which the etching gas is supplied from the first gas supply port 160 in the comparative example. In FIGS. 8 and 9, the flow of the gas is indicated by arrows. The etching gas supplied from the first gas supply port 160 flows along the surface of the reflection surface 15a of the EUV light concentrating mirror 15, and mainly flows into the second space 10b from the first opening 181. At this time, the etching gas forms a flow that suppresses tin fine particles and the like generated in the plasma generation region from passing through the first opening 181 and traveling toward the reflection surface 15a. Further, tin fine particles and the like decelerated and stopped by the flow reversely flow into the second space 10b from the first opening 181 along the flow. Therefore, it is possible to suppress tin fine particles and the like generated in the debris shield 18 from scattering to the first space 10a in which the EUV light concentrating mirror 15 is arranged. Further, as described above, since the etching gas becomes hydrogen radicals due to optical dissociation accompanied by the EUV light generation and removes debris of tin adhering to the reflection surface 15a to generate stannane, the residual gas containing stannane also mainly flows into the second space 10b from the first opening 181. On the other hand, the etching gas supplied from the second gas supply port 170 flows along the surface of the auxiliary plate 25, and flows into the second space 10b from the second opening 182 together with the residual gas at the second gas supply port 170 side from the plane S. The gas flowing in from the first opening 181 and the second opening 182 flows toward the gas exhaust port 189.

In the present embodiment, the amount of the gas flowing into the second space 10b from each of the first opening 181 and the second opening 182 is preferably 20 nlm or more and 60 nlm or less, and the amount of the gas flowing into the second space 10b from each of the laser light inlet opening 183, the droplet supply opening 184, and the laser light outlet opening 186 is preferably 1 nlm or more and 20 nlm or less.

When the droplet DL output from the target supply unit 40 is supplied into the second space 10b through the droplet supply opening 184, the droplet DL is affected by the flow of the gas in the second space 10b. However, in the present embodiment, the first opening 181 and the second opening 182 are provided at symmetrical positions with respect to the plane S. Therefore, the flow of the gas flowing in from the first opening 181 and the flow of the gas flowing in from the second opening 182 are substantially symmetrical with respect to the plane S. Therefore, in the second space 10b, the droplet DL is less affected by the flow of the gas than in a case in which the second opening 182 is not provided or in a case in which the first opening 181 and the second opening 182 are provided at asymmetrical positions with respect to the plane S.

When the droplet DL is irradiated with the laser light 90, the gas density in the plasma generation region AR and the periphery thereof is reduced due to heat and shock waves generated from the droplet DL. However, in the present embodiment, since the flow of the gas flowing in from the first opening 181 and the flow of the gas flowing in from the second opening 182 are substantially symmetrical with respect to the plane S as described above, the direction in which the trajectory of the droplet DL changes is a direction along the optical axis of the laser light 90. Therefore, the droplet is irradiated with the laser light 90 even immediately after the droplet DL is irradiated with the laser light 90.

### 4.3 Effect

In the EUV light generation apparatus 100 of the present embodiment, at least a part of the second opening 182 is provided at a position symmetrical to at least a part of the first opening 181 with reference to the plane S including the trajectory of the laser light 90 and the trajectory of the droplet DL, the first gas supply port 160 is provided on the side at which the first opening 181 is located with reference to the plane S, the second gas supply port 170 is provided on the side at which the second opening 182 is located with reference to the plane S, and the gas in the first space 10a flows into the second space 10b from the first opening 181 and the second opening 182. With such a configuration, immediately after irradiation of the laser light 90, the laser light 90 is prevented from not being radiated onto the droplet DL. Therefore, according to the EUV light generation apparatus 100 of the present embodiment, it is possible to suppress the output of the EUV light 101 from becoming unstable.

Further, in the present embodiment, the target supply unit 40 supplies the droplet DL along the longitudinal direction of the debris shield 18. Therefore, the collection direction of the droplet DL becomes the same as the exhaust direction of the gas. Accordingly, when a tin collection mechanism (not shown) for collecting tin from stannane or tin fine particles flowing together with the etching gas is provided, there is a possibility to integrate the target collection unit 14 and the tin collection mechanism.

### 5. Description of Extreme Ultraviolet Light Generation Apparatus of Second Embodiment

Next, the configuration of the EUV light generation apparatus 100 of a second embodiment will be described. Any component same as that described above is denoted by an identical reference sign, and duplicate description thereof is omitted unless specific description is needed.

### 5.1 Configuration

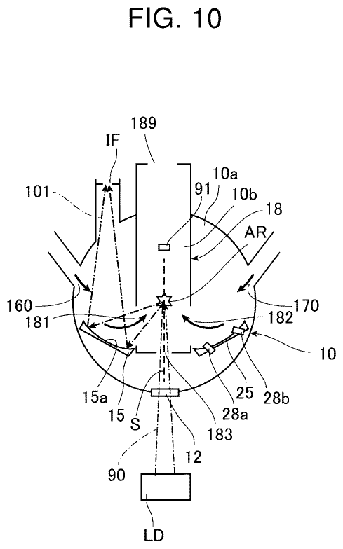

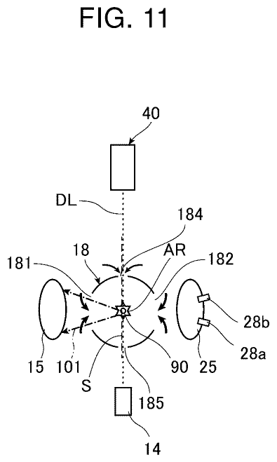

FIG. 10 is a schematic view showing the chamber 10 of the EUV light generation apparatus 100 of the present embodiment in a cross section along the longitudinal direction of the debris shield 18, and FIG. 11 is a schematic view showing the configuration of a part of the inside of the chamber 10 in a cross section perpendicular to the longitudinal direction of the debris shield 18. Here, in FIG. 11, the plane S is shown slightly shifted from the trajectory of the droplet DL.

The EUV light generation apparatus 100 of the present embodiment differs from the EUV light generation apparatus 100 of the first embodiment in that the longitudinal direction of the debris shield 18 is along the irradiation direction of the laser light 90. Therefore, in the present embodiment, the laser light inlet opening 183 is provided at an end part of the debris shield 18 in the longitudinal direction. The laser damper 91 is provided in the debris shield 18. In the present embodiment, the laser light 90 is radiated along the center axis of the radial direction of the second space 10b. Since the laser light 90 is radiated along the longitudinal direction of the debris shield 18, in the present embodiment, the first opening 181 and the second opening 182 are mirror-symmetrical with respect to the plane S as a mirror plane.

Further, the droplet supply opening 184 and the droplet discharge opening 185 are provided on the side wall of the debris shield 18 in a similar manner as in the comparative example.

### 5.2 Operation

In FIGS. 10 and 11, the flow of the gas is indicated by arrows. In the present embodiment as well, the etching gas supplied from the first gas supply port 160 flows along the surface of the reflection surface 15a of the EUV light concentrating mirror 15, and the etching gas not reacting with tin and the residual gas containing stannane at the first gas supply port 160 side with respect to the plane S mainly flows into the second space 10b from the first opening 181. Further, the etching gas supplied from the second gas supply port 170 flows along the surface of the auxiliary plate 25, and the etching gas not reacting with tin and the residual gas containing stannane at the second gas supply port 170 side with respect to the plane S mainly flows into the second space 10b from the second opening 182.

In the present embodiment as well, the first opening 181 and the second opening 182 are provided at symmetrical positions with respect to the plane S. Therefore, the flow of the gas flowing in from the first opening 181 and the flow of the gas flowing in from the second opening 182 are substantially symmetrical with respect to the plane S. Therefore, in the second space 10b, the droplet DL is less affected by the flow of the gas than in a case in which the second opening 182 is not provided or in a case in which the first opening 181 and the second opening 182 are provided at asymmetrical positions with respect to the plane S.

### 5.3 Effect

According to the EUV light generation apparatus 100 of the present embodiment, it is possible to suppress the output of the EUV light 101 from becoming unstable in a similar manner as the EUV light generation apparatus 100 of the first embodiment. Further, in the EUV light generation apparatus 100 of the present embodiment, the laser light 90 is radiated along the longitudinal direction of the debris shield 18. Therefore, when a tin collection mechanism (not shown) for collecting tin from stannane or tin fine particles flowing together with the etching gas is provided, a component serving as both the laser damper 91 and the tin collection mechanism can be arranged.

Although the embodiments of the present invention have been described above as examples, the above-described embodiments can be modified as appropriate. For example, the debris shield 18 may have a shape different from those of the above-described embodiments.

Further, the auxiliary plate 25 may have a shape different from those of the above-described embodiments as long as the auxiliary plate is a plate-shaped member that guides the gas supplied from the second gas supply port 170 to the second opening 182. Further, the EUV light generation apparatus 100 of the present invention may not include the auxiliary plate 25. However, it is preferable to include the auxiliary plate 25 because the difference between the amount of the gas supplied from the first gas supply port 160 and flowing into the second space 10b through the first opening 181 and the amount of the gas supplied from the second gas supply port 170 and flowing into the second space 10b through the second opening 182 can be reduced.

Further, in the above-described embodiments, the sensors 28a, 28b may be provided in the debris shield 18 in a similar manner as in the comparative embodiment. Further, the sensors 28a, 28b may be provided in the chamber 10, and an opening for the sensors 28a, 28b to monitor the inside of the second space 10b may be provided in the debris shield

The gas supplied from the first gas supply port 160 and the gas supplied from the second gas supply port 170 may be different from each other. For example, the etching gas may be supplied from the first gas supply port 160 as in the above-described embodiments and the inert gas may be supplied from the second gas supply port 170. However, as in the embodiments, the gas supplied from the first gas supply port 160 and the gas supplied from the second gas supply port 170 are preferably of the same type.

In the above-described embodiments, the gas supply port is configured of the first gas supply port 160 and the second gas supply port 170. However, the present invention is not limited to this, and the gas supply port may be configured by one supply port or by three or more supply ports.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An extreme ultraviolet light generation apparatus comprising:
a chamber in which a target substance supplied to a plasma generation region at an internal space thereof is irradiated with laser light to generate extreme ultraviolet light;
a target supply unit configured to supply a droplet of the target substance toward the plasma generation region;
a light concentrating mirror arranged at the internal space and configured to concentrate the extreme ultraviolet light;
a debris shield provided with a first opening through which the extreme ultraviolet light passes from the plasma generation region toward the light concentrating mirror and a second opening, and surrounding the plasma generation region;
a gas supply port provided at the chamber and configured to supply a gas to the internal space; and
an exhaust port configured to exhaust a gas in a space surrounded by the debris shield,
at least a part of the second opening being provided at a position symmetrical to at least a part of the first opening with reference to a plane including a trajectory of the laser light and a trajectory of the droplet, and
the gas at the internal space flowing into the space through the first opening and the second opening.

2. The extreme ultraviolet light generation apparatus according to claim 1,
wherein the debris shield has a cylindrical shape in which a longitudinal direction thereof extends in an exhaust direction of the gas.

3. The extreme ultraviolet light generation apparatus according to claim 2,
wherein the target supply unit supplies the droplet along the longitudinal direction.

4. The extreme ultraviolet light generation apparatus according to claim 2,
wherein the laser light is radiated along the longitudinal direction.

5. The extreme ultraviolet light generation apparatus according to claim 2,
wherein an inner diameter of the debris shield is 90 mm or more and 160 mm or less.

6. The extreme ultraviolet light generation apparatus according to claim 1,
wherein the first opening and the second opening are mirror-symmetrical with respect to the plane as a mirror plane.

7. The extreme ultraviolet light generation apparatus according to claim 1,
wherein a same amount of the gas flows in through the first opening and the second opening, respectively.

8. The extreme ultraviolet light generation apparatus according to claim 1,
wherein the first opening and the second opening have a same area.

9. The extreme ultraviolet light generation apparatus according to claim 1,
wherein the first opening and the second opening have a same shape.

10. The extreme ultraviolet light generation apparatus according to claim 1,
wherein each of the first opening and the second opening has a larger area than any other openings provided in the debris shield expect for the exhaust port.

11. The extreme ultraviolet light generation apparatus according to claim 1,
wherein the first opening and the second opening overlap each other by 95% or more in a direction perpendicular to the plane.

12. The extreme ultraviolet light generation apparatus according to claim 1,
wherein the gas supply port includes a first gas supply port provided on a side at which the first opening is located with reference to the plane and a second gas supply port provided on a side at which the second opening is located with reference to the plane.

13. The extreme ultraviolet light generation apparatus according to claim 12,
wherein at least a part of the second gas supply port is provided at a position symmetrical to at least a part of the first gas supply port with respect to the plane.

14. The extreme ultraviolet light generation apparatus according to claim 12,
further comprising an auxiliary plate configured to guide the gas supplied from the second gas supply port to the second opening,
wherein the light concentrating mirror guides the gas supplied from the first gas supply port to the first opening.

15. The extreme ultraviolet light generation apparatus according to claim 14,
wherein at least a part of the auxiliary plate is provided at a position symmetrical to the laser light concentrating mirror with respect to the plane.

16. The extreme ultraviolet light generation apparatus according to claim 15,
wherein the auxiliary plate has a concave shape recessed in a direction symmetrical to a direction in which the light concentrating mirror is recessed with respect to the plane.

17. The extreme ultraviolet light generation apparatus according to claim 16,
wherein the auxiliary plate has a same shape as the light concentrating mirror.

18. The extreme ultraviolet light generation apparatus according to claim 14,
wherein a sensor for observing a state in the space through the second opening is attached to the auxiliary plate.

19. An electronic device manufacturing method, comprising:
outputting extreme ultraviolet light generated using an extreme ultraviolet light generation apparatus to an exposure apparatus; and
exposing a photosensitive substrate to the extreme ultraviolet light in the exposure apparatus to manufacture an electronic device,
the extreme ultraviolet light generation apparatus including:
a chamber in which a target substance supplied to a plasma generation region at an internal space thereof is irradiated with laser light to generate the extreme ultraviolet light;
a target supply unit configured to supply a droplet of the target substance toward the plasma generation region;
a light concentrating mirror arranged at the internal space and configured to concentrate the extreme ultraviolet light;
a debris shield provided with a first opening through which the extreme ultraviolet light passes from the plasma generation region toward the light concentrating mirror and a second opening, and surrounding the plasma generation region;
a gas supply port provided at the chamber and configured to supply a gas to the internal space; and
an exhaust port configured to exhaust a gas in a space surrounded by the debris shield,
at least a part of the second opening being provided at a position symmetrical to at least a part of the first opening with reference to a plane including a trajectory of the laser light and a trajectory of the droplet, and
the gas at the internal space flowing into the space through the first opening and the second opening.

20. An electronic device manufacturing method, comprising:
inspecting a defect of a mask by irradiating the mask with extreme ultraviolet light generated using an extreme ultraviolet light generation apparatus;
selecting the mask using a result of the inspection; and
exposing and transferring a pattern formed on the selected mask onto a photosensitive substrate,
the extreme ultraviolet light generation apparatus including:
a chamber in which a target substance supplied to a plasma generation region at an internal space thereof is irradiated with laser light to generate the extreme ultraviolet light;
a target supply unit configured to supply a droplet of the target substance toward the plasma generation region;
a light concentrating mirror arranged at the internal space and configured to concentrate the extreme ultraviolet light;
a debris shield provided with a first opening through which the extreme ultraviolet light passes from the plasma generation region toward the light concentrating mirror and a second opening, and surrounding the plasma generation region;
a gas supply port provided at the chamber and configured to supply a gas to the internal space; and
an exhaust port configured to exhaust a gas in a space surrounded by the debris shield,
at least a part of the second opening being provided at a position symmetrical to at least a part of the first opening with reference to a plane including a trajectory of the laser light and a trajectory of the droplet, and
the gas at the internal space flowing into the space through the first opening and the second opening.
